(19) United States
(12) Patent Application Publication
(10) Pub. No.: US 2013/0133739 A1
(43) Pub. Date: May 30, 2013

(54) PROCESS FOR PARTICLE DOPING OF SCATTERING SUPERSTRATES

(71) Applicants: Glenn Eric Kohnke, Corning, NY (US); Shawn Michael O'Malley, Horseheads, NY (US); Vitor Marino Schneider, Painted Post, NY (US)

(72) Inventors: Glenn Eric Kohnke, Corning, NY (US); Shawn Michael O'Malley, Horseheads, NY (US); Vitor Marino Schneider, Painted Post, NY (US)

(73) Assignee: CORNING INCORPORATED a New York Corporation

(21) Appl. No.: 13/812,976

(22) PCT Filed: Aug. 29, 2011
(86) PCT No.: PCT/US2011/049511

§ 371 Date: Jan. 29, 2013

Related U.S. Application Data
(60) Provisional application No. 61/378,595, filed on Aug. 31, 2010.

(51) Int. Cl. B05D 5/06; H01L 31/0216

(52) U.S. Cl. CPC B05D 5/061; H01L 31/0216
USPC 136/256; 427/162

(57) ABSTRACT

Light scattering substrates made by providing a substrate comprising at least one surface, forming a layer of particles by depositing a sol-gel on the at least one surface, and heating the coated substrate.

This application claims the benefit of priority under 35 U.S.C. §119 of U.S. Provisional Application Ser. No. 61/378,595 filed on Aug. 31, 2010 the content of which is relied upon and incorporated herein by reference in its entirety.

### BACKGROUND

1. Field

Embodiments relate generally to light scattering substrates and methods for making light scattering substrates, useful for, for example, photovoltaic cells.

2. Technical Background

For thin-film silicon photovoltaic solar cells, light must be effectively coupled into the silicon layer and subsequently trapped in the layer to provide sufficient path length for light absorption. A path length greater than the thickness of the silicon is especially advantageous at longer wavelengths where the silicon absorption length is typically tens to hundreds of microns. Light is typically incident from the side of the deposition substrate such that the substrate becomes a superstrate in the cell configuration. A typical tandem cell incorporating both amorphous and microcrystalline silicon typically has a substrate having a transparent electrode deposited thereon, a top cell of amorphous silicon, a bottom cell of microcrystalline silicon, and a back contact or counter electrode.

Amorphous silicon absorbs primarily in the visible portion of the spectrum below 700 nanometers (nm) while microcrystalline silicon absorbs similarly to bulk crystalline silicon with a gradual reduction in absorption extending to ˜1200 nm. Both types of material benefit from textured surfaces. Depending on the size scale of the texture, the texture performs light trapping and/or reduces Fresnel loss at the Si/substrate interface.

Many additional methods have been explored for creating a textured surface prior to TCO deposition. These methods include sandblasting, polystyrene microsphere deposition and etching, and chemical etching. These methods related to textured surfaces can be limited in terms of the types of surface textures that can be created.

Micro-textured glass has been explored for other applications including hydrophobic coatings. A method of depositing high temperature nanoparticles or microparticles onto a hot glass substrate was developed by Ferro Corporation. In this technique, particles are sprayed onto a substrate while it is on a hot float bath. The technique does not offer control over particle depth, the uniformity of the surface coverage is unknown, and it is unclear if monolayer deposition is possible. Coatings formed by nanoparticle deposition on hot glass substrates were also investigated by both PPG and Beneqoy.

US Patent Application 2007/0116913 discusses particle deposition or direct imprinting on glass coming off an isopipe in a fusion process. Particle deposition may occur above the fusion pipe, along the side of the fusion pipe, or below the fusion pipe. Generally described is the use of any type of glass particles and specifically described is the use of glass particles that are the same composition as the fusion glass. Also described is the use of high temperature particles which are subsequently removed to form features.

The use of surface roughness for creating of scattering centers is well known in the literature. Subtractive processes such as wet chemical etching or mechanical removal of material through grinding/lapping or sandblasting are the most common. These techniques have limits in terms of the types of surface texture they can create. Also there are a substantial amount of techniques for scattering based on volumetric changes inside a host. In cases that employ volumetric scattering throughout the bulk of a material, these often use materials that are expensive for low-cost, large-area applications. As discussed below, there are some existing approaches to creating relatively thin films with volumetric scattering on non-scattering substrates.

An approach to the light-trapping requirements for thin film silicon solar cells was developed by Pacific Solar and currently in the patent portfolio of CSG Solar. The substrate beneath the silicon film is textured and that texture provides light trapping functionality in the Si layer. The texturing consists of SiO₂ particles in a binder matrix deposited on a planar glass substrate. This is done using a sol-gel type process where the particles are suspended in liquid, the substrate is drawn through the liquid, and subsequently sintered. The beads remain spherical in shape and are held in place by the sintered gel. The film thickness is less than the diameter of the beads resulting in a textured surface.

Volumetric and surface texture scattering approaches are known for OLED light extraction. There are a number of publications that discuss volumetric scattering layers where particles are disposed in a binder. The binder is commonly an organic material and contains inorganic scattering particles. WO200237580 (A1) discloses many variations of volumetric scattering layers for OLED light extraction including a layer consisting of scattering particles in a glass frit. EP1603367 discloses the fabrication of a scattering layer on a substrate by the use of particles dispersed in a resin or sol and applied to a substrate for OLED light extraction. U.S. Pat. No. 6,777,871 (B2) also discloses a scattering layer for OLED light extraction that contains scattering particles in a glass or polymer matrix.

It would be advantageous to have a method for making a light scattering substrate wherein a layer or multiple layers of particles could be formed on the substrate.

### SUMMARY

Methods for making a light scattering substrate, as described herein, address one or more of the above-mentioned disadvantages of conventional methods and may provide one or more of the following advantages: the glass microstructure coated with TCO may be smoothly varying and less likely to create electrical problems, the glass texture may be optimized without concern of an absorption penalty unlike in the case of a textured TCO more texture requires regions of thicker TCO resulting in higher absorption, the process does not require a binder that can be sintered as in the case of sol-gel processes, and the texture feature size may be controlled with the particle size distribution.

One embodiment is a method for making a light scattering substrate comprising providing a substrate comprising at least one surface, forming a layer of particles by depositing a sol-gel comprising particles and a binding material on the at least one surface to form a coated substrate, and heating the coated substrate to form the light scattering substrate.

The light scattering substrates can be used in thin film photovoltaic solar cells.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1A is an illustration of a light scattering superstrate according to one embodiment.

FIG. 1B is an illustration of a light scattering superstrate according to one embodiment.

FIG. 2A is a UV-laser confocal microscope image of a light scattering superstrate made according to one embodiment.

FIG. 2B is a UV-laser confocal microscope image of a light scattering superstrate made according to one embodiment.

FIG. 3 is a plot of profile traces (randomly taken) of the glass surface profile with a UV-laser confocal microscope.

FIGS. 4-13 are graphs of light scattering results of light scattering superstrates according to some embodiments.

FIG. 14 is an illustration of features of a photovoltaic device, according to one embodiment.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

Light scattering substrates can be useful for a multitude of applications, more notably Photovoltaics, Display backplane illumination, Lighting applications, anti-fingerprint, and/or anti-smudge, etc. In general, these applications all can benefit from light scattering substrates that combine very high total transmission with a large percentage of diffuse transmission which is often further desired to be scattered at large angles. Many of these applications are particularly cost sensitive and require processes that are not complex and use low-cost materials.

The light scattering substrate methods of making disclosed herein uses a mixture of volumetric and surface light scattering techniques combined with the unique versatility of spin-on-glass or sol-gel technology. The result is a device, for example, glass based, that can vary from being a surface scatterer to a volumetric scatterer depending on the size of the particles embedded on the spin-on-glass and the number of layers deposited, among other parameters. Although spin-on-glass solutions as well as sol-gels have been largely deposited by spin coating, such solutions as well as typical photo resist are not limited to spin-coating. Dip-coating and spray-coating are also alternatives that could also be used to apply the sol-gel.

One embodiment is a method for making a light scattering substrate comprising providing a substrate comprising at least one surface, forming a layer of particles by depositing a sol-gel comprising particles and a binding material on the at least one surface to form a coated substrate, and heating the coated substrate to form the light scattering substrate.

In one embodiment, micro and nanoparticles with high refractive index can be used as scattering material encapsulated within a sol-gel or spin-on-glass matrix. For example, the particles can be silicon-carbide in crystalline form. However, other materials with high refractive index such as titania (or rutile in crystalline form or titania in other crystalline phases), diamond powders can be used.

In one embodiment, the particles, for example, with high refractive index, can be partially buried or totally buried for easier assembly with electronic processes or for tailoring light scattering properties.

Using spin-coating, dip-coating or spray coating would allow a high degree of control over the properties of the surface of the light scattering device being fabricated. The use of such widespread materials in bulk form can lead to an inexpensive and scalable manufacturing process.

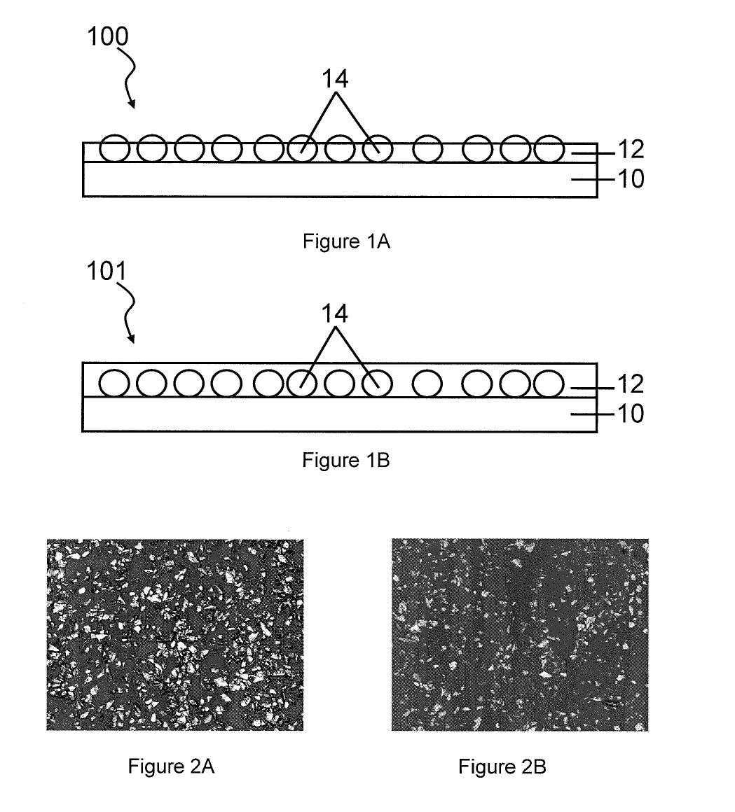

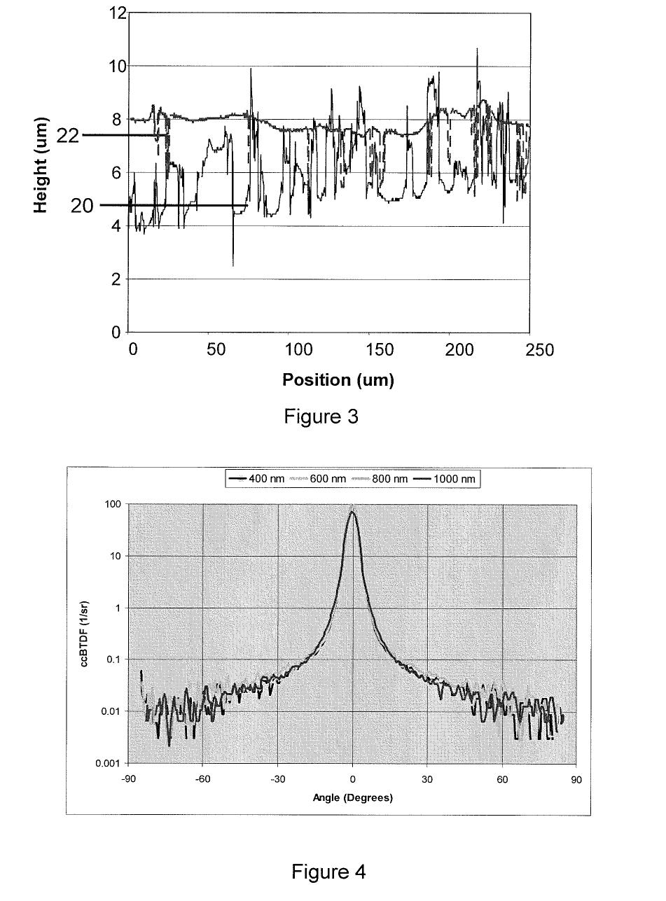

The resultant light scattering substrate made according to the methods disclosed herein can be at least either a surface light scattering substrate or a volumetric light scattering substrate. In one embodiment, as shown in FIG. 1A, the light scattering substrate 100 comprises an aggregate of particles 14 attached to a surface of a substrate 10 bound by a binding material 12 that is compatible with the substrate such as a sol-gel, a spin-on-glass or polymer. The particles, in this example, can have structures that are larger than the binding layer and therefore comprises a surface roughness. This is an example of a surface light scattering substrate.

In another embodiment, as shown in FIG. 1B, the light scattering substrate 101 comprises an aggregate of particles 14 attached to a surface of a substrate 10 bound by a binding material 12 that is compatible with the substrate such as a sol-gel, a spin-on-glass or polymer. In this embodiment, either the particles are smaller than the thickness of the binding material (binding layer) and/or the devices after the initial deposition with particles larger than the thickness of the bind layer is further processes by multiple layers of binding material to bury the particles inside a thicker layer of binding material. An example of this volumetric scattering substrate can be then observed in FIG. 1B. The possibility of having either condition or something in between these two conditions provide means to better control the surface planarity of the scattering device and it is advantageous for subsequent processing of devices on the same substrate.

In one embodiment, the substrate is a glass substrate. Other substrates may be used without limitation such as polymer, plastic, glass-ceramic, ceramics, fibers, synthetic sapphires and various crystals.

According to one embodiment, the method of making the light scattering superstrates comprises providing precursors, for example, a binding material and a powder, mixing the precursors, for example, at a desired ratio (e.g. 1:10 per weight), dispensing the mixed precursors on a substrate, for example, a soda-lime glass, and heating the coated substrate.

Dispensing the precursors on the substrate can be performed by, for example, spin coating, spray-coating, dip-coating, etc.

The coated substrate can be heated, for example, by baking to sinter and consolidate at a certain temperature (it can be low temperature depending on the sintering temperature of the particles, the gel, or the softening temperature of the substrate).

The steps can be repeated multiple times for multiple layers or burial of the particles and/or layers with a binding material. In one embodiment, the binding material is optically transparent or clear.

For proof of principle different precursors were tested. In the case of the binding material typical silicate based sol-gel solutions, spin-on-glass or even polymers that can be photosensitive or not could be used as a binding material. In this particular case we used a commercial spin-on-glass solution due to its long shelf life time and low temperature of sintering. The product is called Intermediate Coating IC1-200 made by Futurrex, Inc. The powder used however varied. We tried several different available powders, the most successful ones included SiC crystalline powder with ˜4 um particle size made by www. Silone-sic.com. The powders are partially transparent but with a high refractive index leading to light scattering under the microscope illumination. Therefore the initial choice for the SiC powder used is advantageous to control over the final scattering quality. However, titanium oxide with 5 um particle size and zinc oxide nanopowders with dimensions between 40 nm-100 nm were also used. Powders were preferentially chosen for targeting higher index of refraction and shining under natural conditions. Therefore powders such as crystalline silicon-carbide (SiC), diamond powder, titanium dioxide (rutile crystalline form also possible), could be quite attractive.

The mixing of the precursors can be done in a variety of methods. For example, mixing on a volume/weight basis assuming the density of the Futturex spin-on-glass solution as being the density of water was used. 1 mg of SiC powder was mixed with 10 ml of Futturex spin-on-glass leading to a 1:10 solution. All examples described herein were based on a 1:10 solution.

The deposition can be done according to several different methods, for example, spin-coated, spray-coated, dip-coated, tape casted and other possible ways, for example, to deposit polymers (such as photoresist). Therefore, current equipment available for deposition of photoresist used in the large size display glass panel business can (with some small modifications in some cases due to the particle size used) be used for this deposition process. In this example, a spin-coating method was used to deposit the Futurrex IC1-200 coating. The precursor mix was deposited onto a glass slide with a pipette and the spinner was set for velocities varying from 1000 RPM (thicker layer)-4000 RPM (thinner layer) for a duration of 60 seconds. The result was a thick film with particles dispersed on the glass substrate that was partially wet.

After the film is produced with the particles, heating, for example, sintering may provide a stable long lasting film on the substrate. The sintering can be done in a vertical furnace, tube furnace, rapid thermal annealer (RTA) or on a simple hot-plate. In this example, a hot-plate was used with sintering at 240° C. for 5 minutes. If the device is to be completed with a single layer a further sintering at 240° C. for 30 minutes would be recommended but not strictly necessary.

The method according to one embodiment, further comprises forming another layer of particles by depositing a sol-gel comprising particles and a binding material on the coated substrate after the heating.

The method according to one embodiment, comprises repeating the forming, and the heating to form the light scattering substrate, wherein the light scattering substrate comprises multiple layers of particles.

The method according to one embodiment, further comprises depositing a layer of binding material by depositing a sol-gel comprising a binding material on the coated substrate after the heating.

The method according to claim 9, comprising repeating the heating and the depositing a layer of binding material to form the light scattering substrate, wherein the light scattering substrate comprises multiple layers of the binding material.

If multiple layers are needed the forming or depositing or both steps and the heating steps should be repeated in a loop. For multiple layers of particles coating the process is repeated with the same precursor mix. However, if one wants to bury the particles and ‘planarize’ the surface a clear Futurrex IC1-200 or desired adhesion chemical used to bury the light scattering substrate with multiple layers. In one of the experiments we conducted with buried a SiC particles containing film with 10 layers of clear spin-on-glass coating. Once completed, the light scattering substrate whether buried or not, can be characterized for its scattering efficiency.

Several slides were coated with particles using the spin-coated process mentioned above.

The following is a description of the various micro and nano powder materials (particles) that were tried:

SiC powder with 20 um particle size;

SiC powder with 4 um particle size;

titanium oxide powder with 5 um particle size;

titanium oxide powder with 90 nm particle size;

aluminum oxide powder with ˜100 nm particle size; and

zinc oxide powder with 40 nm-100 nm particle size.

From these trials listed above the ones that presented the more positive results were:

SiC powder with 4 um particle size;

titanium oxide powder with 5 um particle size; and

zinc oxide powder with 40 nm-100 nm particle size.

Some of the nanopowders (nanoparticles) became clustered during spinning making a rough surface. Agglomeration of nanopowders is very common (perhaps due to electrostatics). A more exhaustive matching between particle size and sol-gel spin coating conditions is likely to overcome some of the agglomeration challenges. For example, pre-coating the scattering particles with silanes which limit self agglomeration is also contemplated as a useful processing pre-treatment. The SiC powder with 20 um particle size works well but it does not lead to as good of scattering results when compared to conventional films.

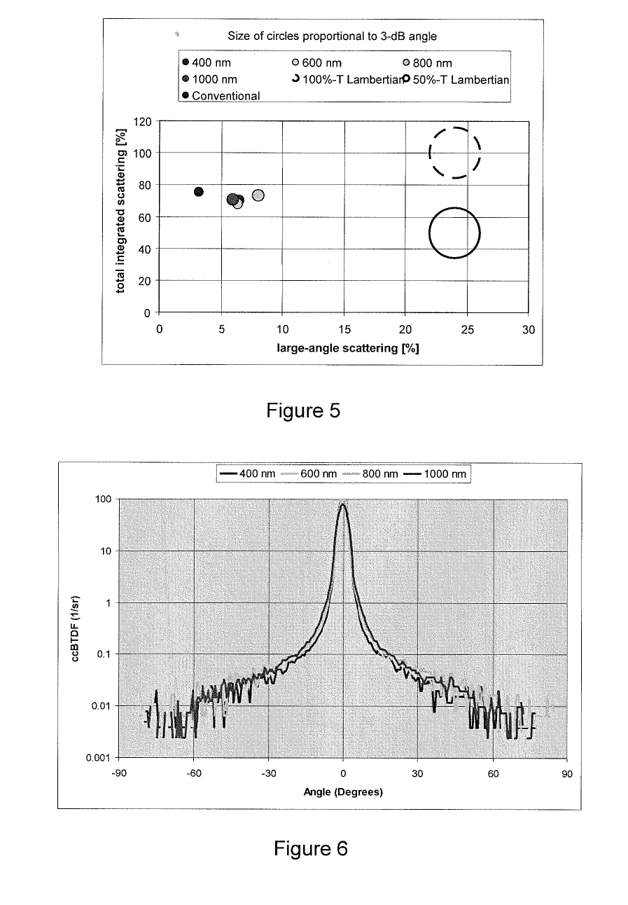

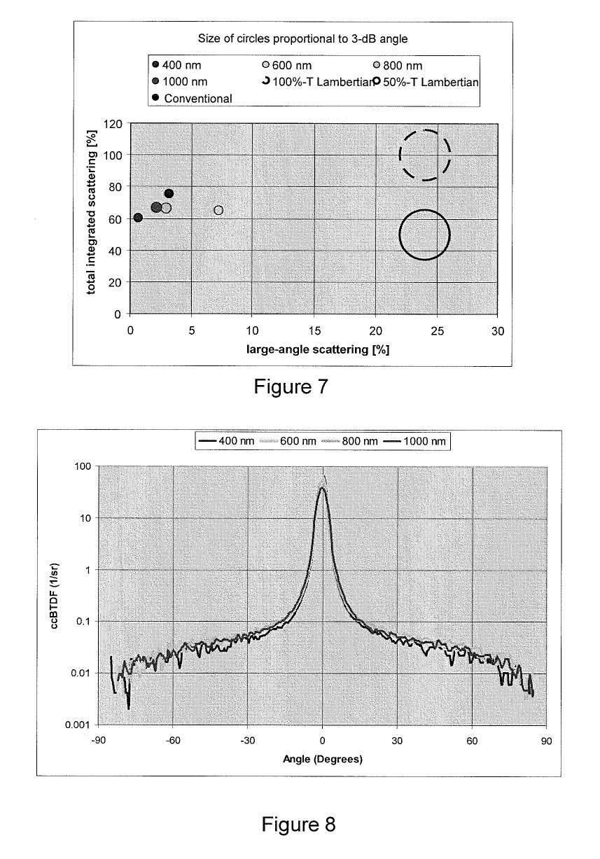

A UV-confocal image showing a top down view of a light scattering substrate, according to one embodiment, is shown in FIG. 2A. The light scattering substrate was made using a sol-gel comprising SiC with a 4 um particle size and spin-on-glass. The surface of the sintered glass slide was observed with an optical microscope and with a UV-laser confocal microscope. In this case the light scattering substrate was made with a solution of 1:10 and spin speed of 1000 RPM and sintering at 240° C. for 5 minutes. The same process was repeated with several clean (without particles) coating layers of Futurrex IC1-200 spin-on-glass. In this case 10 layers were used with the intent to planarize the device. A top down UV-confocal image is shown in FIG. 2B.

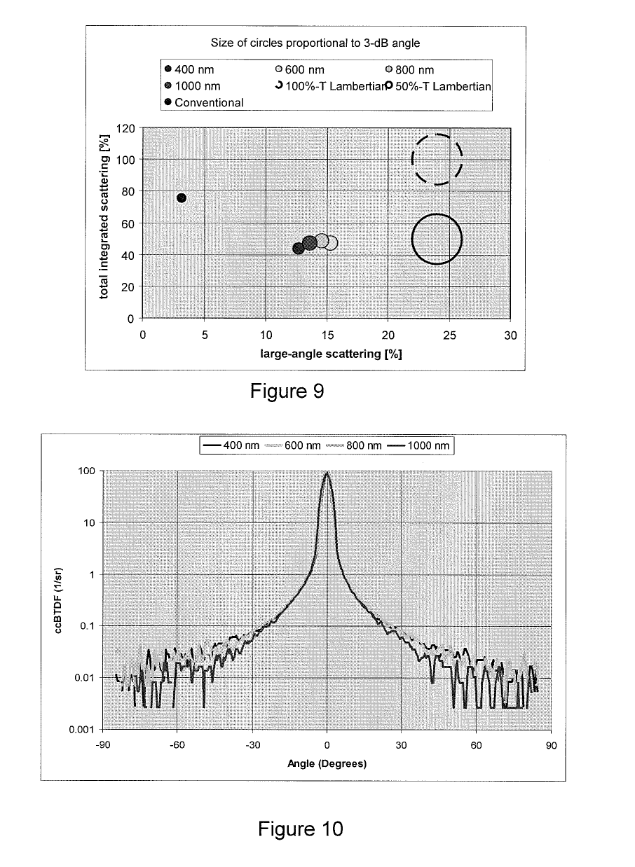

With the use of a confocal microscope and changing the focal point of the image an approximated 3D representation of the surface can be made. A trace of a single layer of the 1:10 solution with SiC 4 um particle size can be observed in FIG. 3 by line 20. Here one can see the average 4 um height of the particles. The sample was then coated for burial with 10 layers of clean IC1-200 coating. The profile now can also be observed in FIG. 3 by line 22. Here one can see that the light scattering substrate is mostly planar but now one can observe dips that are probably areas where the coating did not penetrate underneath the particles leading to some voids in the film. If this process in continuously repeated one can increase the planarization of the light scattering substrate to a desired level.

Scattering measurements are quantified by their total integrated scatter which corresponds total transmittance but is not as accurate as a spectrophotomer measurement. Also, the percentage of light at angles greater than 50 degrees is also calculated to quantify the large angle scattering. The 3 dB angle is defined as the angle at which half the light intensity is at smaller and larger angles. The total integrated scatter, large angle scattering, and 3 dB angle are compared with a conventional light scattering superstrate measured using a bubble plot.

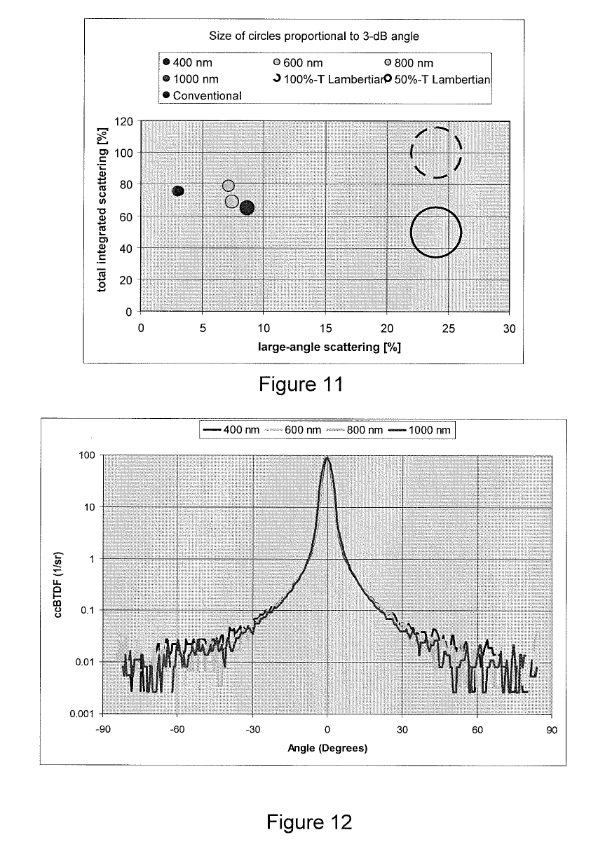

The films were characterized with a Radiant Imaging IS-SA scattering measurement system with light incident on-axis on the uncoated side of the substrate. FIG. 4 and FIG. 5 show the scattering results and bubble plot, respectfully, at 400, 600, 800, and 1000 nm for a single SiC 4 um powder in a 1:10 mixture made by spin coating at 1000 RPM and sintering at 240° C. for 5 minutes. Here one can notice that the total light scattering is close to 75% with significant small angle scattering and no wavelength dependence.

Additional measurements were done with the previous light scattering substrate now with a post processing of burying the device under 10 layers of clear spin-on-glass solution. Such light scattering substrate that has a planar surface with voids as described in FIGS. 2A and 2B. The measurements in this case can be observed in FIGS. 6 and 7. Here the device has somewhat less small angle scattering compared with FIGS. 4 and 5. The advantage here is that one can control the degree of flatness of the substrate and the effect seems to be embedded in the volume of the buried film.

In order to increase the angle of scattering, the ratio of the spin-on-glass:powder can be changed (here we used 10:1 all the time), but one can imagine that this has some limits as the solution becomes too viscous and full of sediments. One alternative is to use multiple coatings of doped solution with particles to increase the density of particles per facet coated. 4 coatings of particle doped solution on a glass surface were also done. The measured results can be observed in FIGS. 8 and 9. The results indicate that the angle of scattering increases with the number of coatings. However, there is a reduction in total intensity of light scattered. Therefore a trade-off seems to occur.

In addition to SiC powder, several nanopowders were used to make light scattering substrates. Light scattering substrates were made using dope Zinc Oxide (ZnO) nanopowders with 40 nm-100 nm particle sizes in a 10:1 ratio and spin coating at 1000 RPM with sintering at 240° C. The results for a single layer on a glass slide can be observed in FIGS. 10 and 11. The layer has a significant amount of small angle scattering, some large angle scattering, and no wavelength dependence.

This ZnO layer was then post processed and buried with a single layer of clear spin-on-glass. Measurements of the resulting light scattering substrates can be seen in FIGS. 12 and 13. There is a reduction in the large angle scattering of the resulting light scattering substrates as compared with the light scattering substrates of FIGS. 10 and 11.

Embodiments described herein may provide one or more of the following advantages: low-cost of manufacturing; scalability to large sizes (equipment used in photoresist coating of large display panels can be used here); low-temperature process and compatible with display glass, soda-lime and low temperature glasses; can be ‘tuned’ between a surface scatterer and a volumetric scatterer by the use of multilayers; may provide a flat (or flatter) surface that would be beneficial for deposition of other devices; may be used with a variety of different high index micro and nano-powders; may be processed by spin-coating, dip-coating, spray-coating and other photoresist deposition techniques; and/or may be easily integrated in a display platform for imaging, lighting, energy conversion and other applications.

Embodiments may show superior performance in light scattering than conventional light scattering substrates, used as industry standard for thin-film Si photovoltaic solar cells. In some embodiments, spin-on-glass and SiC crystalline powder was used. Other kinds of sol-gels and/or other powders with high refractive index such as titania and diamond powder may also be used.

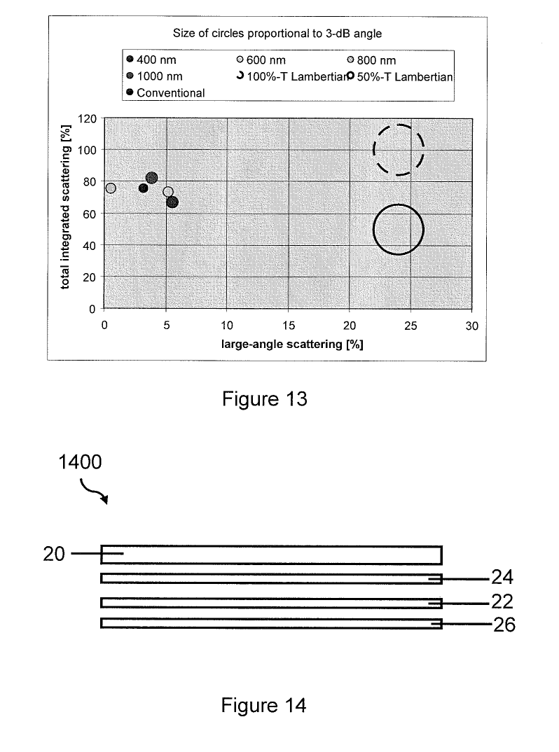

One embodiment, features of which are shown in FIG. 14, is a photovoltaic device 1400 comprising the light scattering inorganic substrate 20 according to embodiments disclosed herein. The photovoltaic device, according to one embodiment further comprises a conductive material 24 adjacent to the substrate, and an active photovoltaic medium 22 adjacent to the conductive material.

The active photovoltaic medium, according to one embodiment, is in physical contact with the conductive material. The conductive material, according to one embodiment is a transparent conductive film, for example, a transparent conductive oxide (TCO). The transparent conductive film can comprise a textured surface.

The photovoltaic device, in one embodiment, further comprises a counter electrode in physical contact with the active photovoltaic medium and located on an opposite surface of the active photovoltaic medium as the conductive material.

According to some embodiments, the sol-gel comprises particles having a different refractive index than the material of the sol they are entrained in. The refractive index can be higher, lower, or the same. When multiple layers are deposited, the particles, sol material, of the each of the layers and between each of the layers can be the same or different. The combinations of various refractive indices can be advantageous to tailor light scattering properties for various wavelengths or for various applications.

The process of manufacturing of a scattering device can be used to produce a surface scatterer, a volume scatterer or a combination of both. The device in question is done with a mixture of spin-on-glass or sol-gel and high index micro or nanoparticles. The process can be scaled easily and it is done a low temperatures being compatible with most types of glasses including display glass and soda-lime glass.

The substrate, in one embodiment, comprises a material selected from a glass, a ceramic, a glass ceramic, sapphire, silicon carbide, a semiconductor, and combinations thereof.

In one embodiment, the particles are inorganic particles and comprise spheres, microspheres, bodies, symmetrical particles, nonsymmetrical particles, or combinations thereof.

In one embodiment, the particles can be of any shape or geometric shape, for example, polygonal. The particles can comprise a material selected from a glass, a ceramic, a glass ceramic, sapphire, silicon carbide, a semiconductor, metal oxides, and combinations thereof.

Generally, any size structures that are generally used by those of skill in the art can be utilized herein. In one embodiment, the structures have diameters of 20 micrometers (μm) or less, for example, in the range of from 100 nanometers (nm) to 20 μm, for example, in the range of from 100 nanometers (nm) to 10 μm, for example, 1 μm to 10 μm can be coated using methods disclosed herein.

In one embodiment, the structures have a distribution of sizes, such as diameter. The diameter dispersion of structures is the range of diameters of the structures. Structures can have monodisperse diameters, polydisperse diameters, or a combination thereof. Structures that have a monodisperse diameter have substantially the same diameter. Structures that have polydisperse diameters have a range of diameters distributed in a continuous manner about an average diameter. Generally, an average size of polydisperse structures is reported as the particle size. Such structures will have diameters that fall within a range of values. Using different sized particles to make the light scattering substrates may lead to enhanced light scattering properties at different wavelengths.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A method for making a light scattering substrate, the method comprising:
providing a substrate comprising at least one surface;
forming a layer of particles by depositing a sol-gel comprising particles and a binding material on the at least one surface to form a coated substrate; and
heating the coated substrate to form the light scattering substrate.

2. The method according to claim 1, wherein the substrate comprises a material selected from a glass, a ceramic, a glass ceramic, sapphire, silicon carbide, a semiconductor, a polymer, and combinations thereof.

3. The method according to claim 1, wherein the particles comprise spheres, microspheres, bodies, symmetrical particles, nonsymmetrical particles, or combinations thereof.

4. The method according to claim 1, wherein the binding material is a glass and the substrate is a glass.

5. The method according to claim 1, wherein the particles comprise a material selected from a glass, a ceramic, a glass ceramic, sapphire, silicon carbide, a semiconductor, metal oxides, and combinations thereof.

6. The method according to claim 1, wherein the particles have an average diameter of 5 microns or less.

7. The method according to claim 1, further comprising forming another layer of particles by depositing a sol-gel comprising particles and a binding material on the coated substrate after the heating.

8. The method according to claim 1, comprising repeating the forming, and the heating to form the light scattering substrate, wherein the light scattering substrate comprises multiple layers of particles.

9. The method according to claim 1, further comprising depositing a layer of binding material by depositing a sol-gel comprising a binding material on the coated substrate after the heating.

10. The method according to claim 9, comprising repeating the heating and the depositing a layer of binding material to form the light scattering substrate, wherein the light scattering substrate comprises multiple layers of the binding material.

11. A photovoltaic device comprising the light scattering substrate made according to the method of claim 1.

12. The device according to claim 11, further comprising
a conductive material adjacent to the substrate; and
an active photovoltaic medium adjacent to the conductive material.

13. The device according to claim 11, wherein the conductive material is a transparent conductive film.

14. The device according to claim 12, wherein the transparent conductive film comprises a textured surface.

15. The device according to claim 12, wherein the active photovoltaic medium is in physical contact with the transparent conductive film.

16. The device according to claim 12, further comprising a counter electrode in physical contact with the active photovoltaic medium and located on an opposite surface of the active photovoltaic medium as the conductive material.
